(19) United States
(12) Patent Application Publication
(10) Pub. No.: US 2025/0275409 A1
(43) Pub. Date: Aug. 28, 2025

(54) TRANSPARENT DISPLAY DEVICE

(71) Applicant: LG Display Co., Ltd., Seoul (KR)

(72) Inventors: Hyeokjun Kwon, Paju-si (KR); Sangbin Lee, Paju-si (KR)

(73) Assignee: LG Display Co., Ltd., Seoul (KR)

(21) Appl. No.: 18/977,453

(22) Filed: Dec. 11, 2024

(30) Foreign Application Priority Data
Feb. 28, 2024 (KR) 10-2024-0029127

(51) Int. Cl. H10K 59/35

(52) U.S. Cl. CPC H10K 59/351; H10K 59/352

(57) ABSTRACT

Disclosed is a transparent display device for mitigating edge artifacts by optimizing the placement of four color light emission areas. The transparent display device may comprise a plurality of pixel regions having a non-transmissive region and a transmissive region and a first subpixel, a second subpixel, a third subpixel, and a fourth subpixel arranged sequentially in a first direction in the non-transmissive region of the plurality of pixel regions. One of the second subpixel and the third subpixel may be a green subpixel, and the other may be a white subpixel. If the second subpixel is a green subpixel, the first subpixel is a red subpixel, or if the third subpixel is a green subpixel, the fourth subpixel is a red subpixel.

### CROSS-REFERENCE TO RELATED APPLICATION

This application claims the benefit of and priority to Korean Patent Application No. 10-2024-0029127, filed on Feb. 28, 2024, which is hereby incorporated by reference as if fully set forth herein.

### BACKGROUND

### Technical Field

The present disclosure relates to a transparent display device that can improve image quality by mitigating edge artifacts.

### Discussion of the Related Art

A transparent display device can include a non-transmissive area and a transmissive area. The non-transmissive area can display full color using four-color subpixels that include white, red, green, and blue emitting areas.

In a four-color transparent display device, the spacing between the emitting subpixels may be increased to display a particular color, or the spacing between the emitting subpixels may be deviated.

As a result, the four-color transparent display device may exhibit edge artifacts, which are perceived as white line, black line, or color fringe at the edges where there is a luminance difference between adjacent pixels, resulting in image quality degradation.

### SUMMARY

Accordingly, the present disclosure is directed to a transparent display device that substantially obviates one or more problems due to limitations and disadvantages of the related art.

An aspect of the present disclosure provides a transparent display device that can mitigate edge artifacts by optimizing the placement of four-color light emitting regions.

To achieve these and other advantages and in accordance with the purpose of the disclosure, as embodied and broadly described herein, a transparent display device may include a display area having a plurality of pixel regions having a non-transmissive region and a transmissive region and a first subpixel, a second subpixel, a third subpixel, and a fourth subpixel arranged sequentially in this order in a first direction in the non-transmissive region of the plurality of pixel regions. In particular, each pixel region may have a non-transmissive region and a transmissive region and a first subpixel, a second subpixel, a third subpixel, and a fourth subpixel arranged sequentially in a first direction in the non-transmissive region of the pixel region. One of the second subpixel and the third subpixel may be a green subpixel, and the other may be a white subpixel. If the second subpixel is a green subpixel, the first subpixel may be a red subpixel, or if the third subpixel is a green subpixel, the fourth subpixel may be a red subpixel.

The first to fourth subpixels may be a red subpixel, a green subpixel, a white subpixel, and a blue subpixel arranged sequentially in the first direction.

The first to fourth subpixels may be a blue subpixel, a white subpixel, a green subpixel, and a red subpixel arranged sequentially in the first direction.

In accordance with another aspect of the present disclosure, a transparent display device may include a display area having a plurality of pixel regions having a non-transmissive region and a transmissive region and a red subpixel, a green subpixel, a white subpixel, and a blue subpixel arranged sequentially in this order in a vertical direction in the non-transmissive region of the plurality of pixel regions. In particular, each pixel region may have a non-transmissive region and a transmissive region and a red subpixel, a green subpixel, a white subpixel, and a blue subpixel arranged sequentially in a vertical direction in the non-transmissive region of the pixel region.

In accordance with yet another aspect of the present disclosure, a transparent display device may include a display area having a plurality of pixel regions having a non-transmissive region and a transmissive region; and a blue subpixel, a white subpixel, a green subpixel, and a red subpixel arranged sequentially in this order in a vertical direction in the non-transmissive region of the plurality of pixel regions. In particular, each pixel region may have a non-transmissive region and a transmissive region; and a blue subpixel, a white subpixel, a green subpixel, and a red subpixel arranged sequentially in a vertical direction in the non-transmissive region of the pixel region.

One or more of these aspects may include on or more of the following features:

The transmissive region may be provided at a left or right side of the non-transmissive region, or at both sides of left and right sides of the non-transmissive region in the plurality of pixel regions.

Each pixel region of the plurality of pixel regions may have a non-transmissive region and a transmissive region.

In each pixel region, the green and white subpixels among the four subpixels in the non-transmissive region may be disposed in the center of the non-transmissive region, and the red and green subpixels may be disposed adjacent to each other.

The first direction may be a vertical direction. The first direction may be a direction of a data line of the pixel region and/or of the transparent display device.

The emission areas of the first, second, third, and fourth subpixels of a pixel region may be arranged side by side in the first direction.

The transmittance of the pixel area may be more than 45%. The transmittance of the pixel area may be at least 55%.

The aperture ratio of the blue subpixel and the aperture ratio of the red subpixel may be larger than the aperture ratio of the white subpixel and the aperture ratio of the green subpixel. The aperture ratio of the first subpixel and the aperture ratio of the fourth subpixel may be larger than the aperture ratio of the second subpixel and the aperture ratio of the third subpixel.

Herein, the terms “area” and “region” are used interchangeably, unless disclosed otherwise, for example, expressly indicated otherwise or implicitly disclosed otherwise. Herein, the terms “transmissive area” and “transmissive region” are used interchangeably. Herein, the terms “non-transmissive area” and “non-transmissive region” are used interchangeably. Herein, the terms “pixel area” and “pixel region” are used interchangeably.

Each of the plurality of pixel regions may include an emissive area where a plurality of subpixels configured for displaying an on-screen image are disposed, and a transmissive area that is configured for transmitting light. The emissive area may be represented by the non-transmissive region, and the transmissive area may be represented by the transparent region. The non-transmissive region may comprise the emissive area.

In each pixel regions, the transmissive area (or region) may be adjacent to the non-transmissive area in a second direction. The second direction may be a horizontal direction. The second direction may be a direction of a gate line of the pixel region and/or of the transparent display device. The second direction may be a left-right direction. The second direction may be perpendicular to the first direction.

The non-transmissive area (or region) may include first to fourth emissive regions of the first to fourth subpixels arranged side-by-side in the first direction. The non-transmissive area (or region) may include a black matrix surrounding the emissive regions. Each subpixel (or the non-transmissive region of each subpixel) may comprise an emissive region and a black matrix surrounding the emissive region.

Herein, a transparent display device is interpreted as including a display device in which each of the plurality of pixel regions includes a transmissive region.

The non-transmissive area may be configured for displaying full color using four-color subpixels that include white, red, green, and blue emitting areas.

It is to be understood that both the foregoing general description and the following detailed description of the present disclosure are by way of example and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure. In the drawings:

FIG. 1 is a block diagram schematically illustrating an example of a configuration of a transparent display device, according to one or more embodiments of the present disclosure.

FIG. 2 is a block diagram schematically illustrating an example of a configuration of a transparent display device, according to one or more embodiments of the present disclosure.

FIGS. 3A to 3C are drawings illustrating examples of a pixel structure, according to one or more embodiments of the present disclosure.

FIGS. 4A to 4C are drawings illustrating examples of pixel structures, according to one or more embodiments of the present disclosure.

FIG. 5 is an equivalent circuit diagram illustrating an example of the configuration of each subpixel, according to one or more embodiments of the present disclosure.

FIG. 6 is an equivalent circuit diagram illustrating an example of the configuration of each subpixel, according to one or more embodiments of the present disclosure.

FIG. 7 is an example diagram illustrating a region of each pixel, according to one or more embodiments of the present disclosure.

FIGS. 8A to 8C are diagrams illustrating transmittance of a transparent display device according to a comparative example and a transparent display device according to one or more embodiments of the present disclosure.

FIG. 9 is an illustration of a color fringe phenomenon according to an arrangement order of three-color subpixels according to a comparative example.

FIGS. 10A to 10C and FIGS. 11A to 11C are diagrams illustrating examples of edge artifact phenomena of a transparent display device according to comparative examples.

FIGS. 12A to 12C are drawings illustrating examples of edge artifact mitigation effects of a transparent display device according to one or more embodiments of the present disclosure.

FIGS. 13A, 13B, 14A, 14B, 15A, and 15B are drawings illustrating examples of edge artifacts of a transparent display device according to a comparative example.

FIGS. 16A and 16B are drawings illustrating examples of an edge artifact mitigation effect of a transparent display device, according to one or more embodiments of the present disclosure.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the protected scope of the present disclosure is defined by scopes of claims and their equivalents.

A shape, a size, a ratio, an angle, and a number disclosed in the drawings for describing aspects of the present disclosure are merely examples, and thus, the present disclosure is not limited to the illustrated details. Like reference numerals refer to like elements throughout the specification. In the following description, where the detailed description of the relevant known function or configuration is determined to unnecessarily obscure the important point of the present disclosure, the detailed description may be omitted. In a case where ‘comprise’, ‘have’, and ‘include’ described in the present specification are used, another part may be added unless a more limiting term like ‘only’ is used. The terms of a singular form may include plural forms, and vice versa, unless referred to the contrary.

In construing an element, the element should be construed as including an error range although there is no explicit description.

In describing a position relationship, for example, where a position relation between two parts is described as “on,” “over,” “under,” and “next,” one or more other parts may be disposed between the two parts unless a more limiting term, such as “just” or “direct (ly),” is used.

In describing a time relationship, for example, where a temporal order is described as, “after,” “subsequent,” “next,” and “before,” a case which is not continuous may be included unless a more limiting term, such as “just,” “immediate (ly),” or “direct (ly)” is used.

It will be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element, without departing from the scope of the present disclosure.

In describing the elements of the present disclosure, the terms “first,” “second,” “A,” “B,” “(a),” “(b),” etc., may be used. These terms are intended merely to identify the corresponding elements separately from the other elements, and are not intended to define or limit the basis, order, sequence, or number of the corresponding elements. As for the expression that an element or a layer is “connected,” “coupled,” or “adhered” to another element or layer, the element or layer may not only be directly connected or adhered to another element or layer, but may also be indirectly connected or adhered to another element or layer with one or more intervening elements or layers “disposed” between the elements or layers, unless otherwise specified.

The term “at least one” should be understood as including any and all combinations of one or more among the associated listed elements. For example, the meaning of “at least one or more of a first element, a second element, and a third element” denotes the combination of all elements proposed from two or more of the first element, the second element, and the third element as well as the first element, the second element, or the third element.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in co-dependent relationship.

Hereinafter, the aspect of the present disclosure will be described with reference to the accompanying drawings. Since a scale of each of elements shown in the accompanying drawings may be different from an actual scale for convenience of description, the present disclosure is not limited to the shown scale. Further, all the components of each display apparatus according to all aspects of the present disclosure may be operatively coupled and configured.

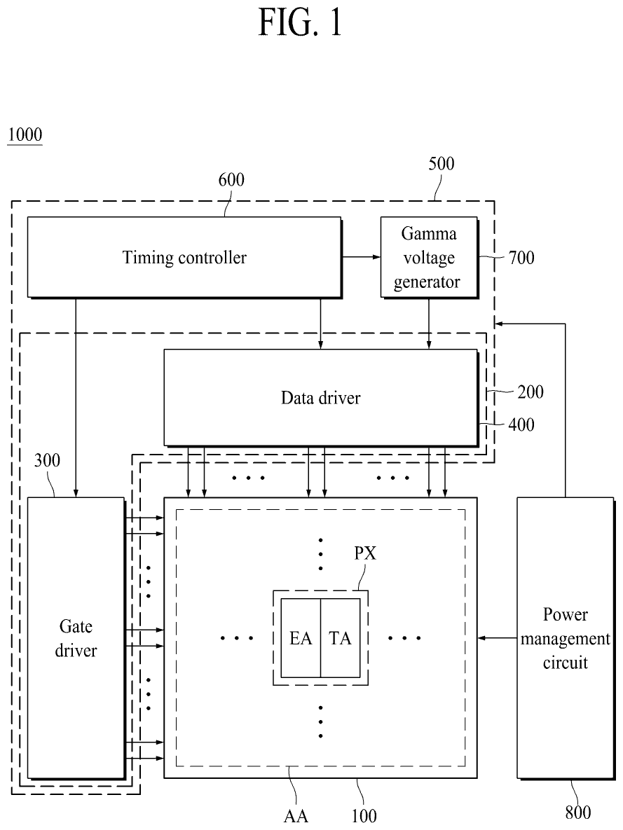

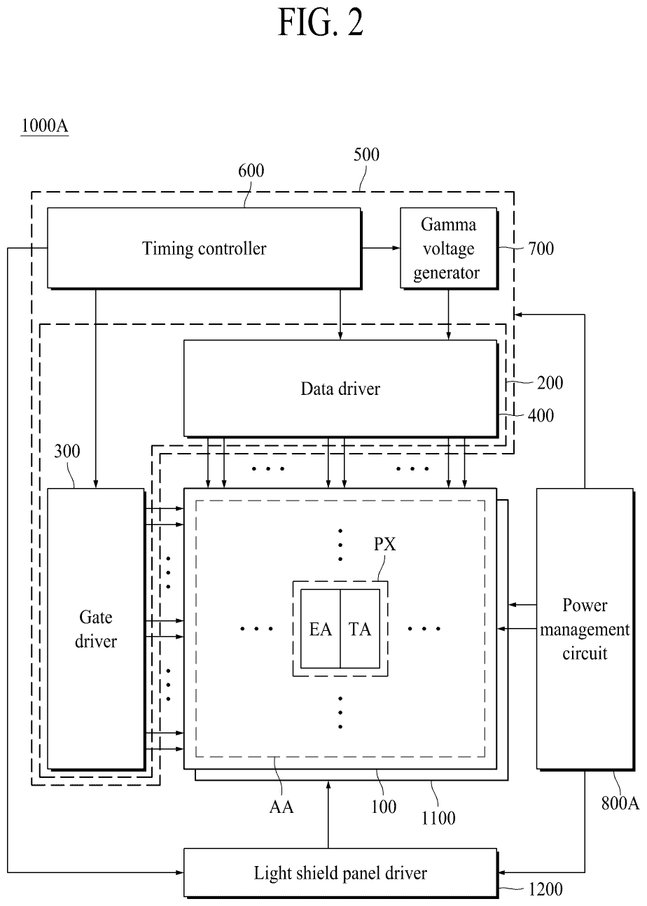

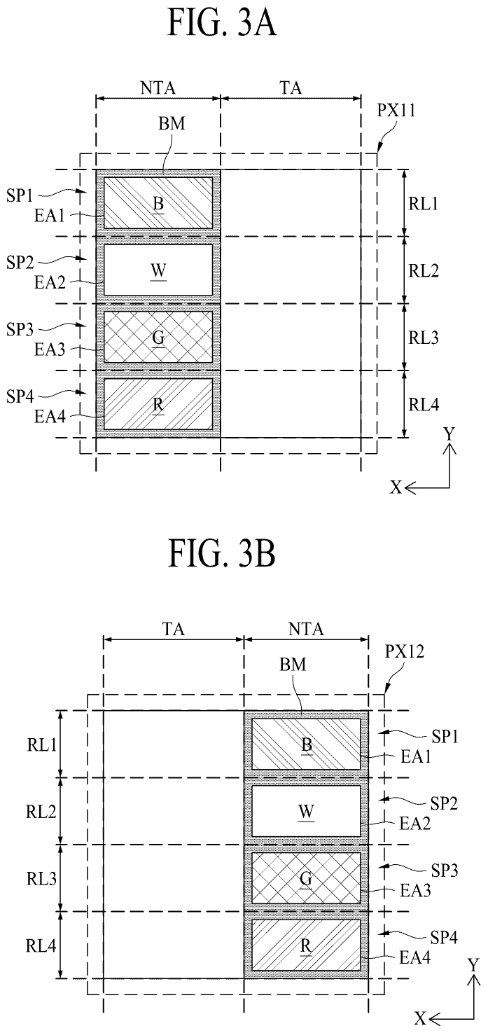

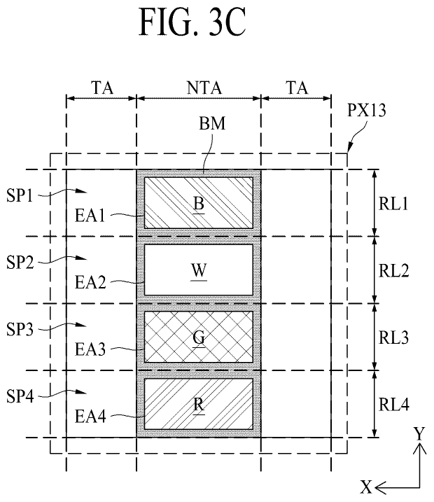

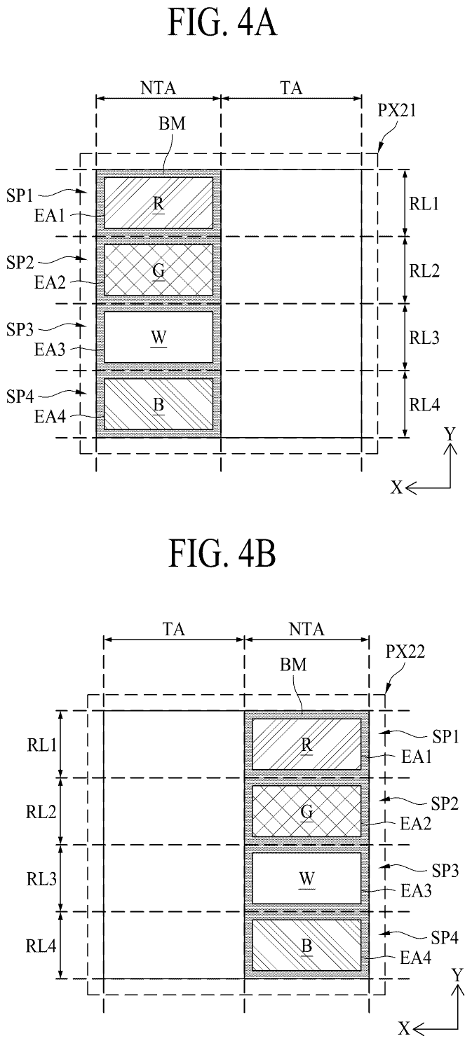

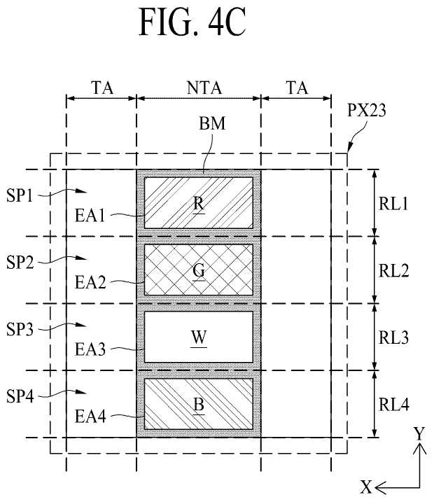

FIGS. 1 and 2 are block diagrams schematically illustrating an example of a configuration of a transparent display device according to one or more embodiments of the present disclosure. FIGS. 3A to 3C and FIGS. 4A to 4C are drawings illustrating examples of a pixel structure according to one or more embodiments of the present disclosure.

The display devices 1000, 1000A according to one or more embodiments may be a liquid crystal display device, an electroluminescent display device utilizing a spontaneous light emitting element, or a micro light emitting diode display device utilizing a micro light emitting diode. The electroluminescent display device may be an Organic Light Emitting Diode (OLED) display device, a Quantum-dot Light Emitting Diode display device, or an Inorganic Light Emitting Diode display device.

As shown in FIGS. 1 and 2, a transparent display device 1000, 1000A according to one or more embodiments may include a display panel 100, a gate driver 300, a data driver 400, a timing controller 600, a gamma voltage generator 700, a power management circuit 800, 800A, and the like. The gate driver 300 and data driver 400 may be represented by the panel driver 200 driving the display panel 100. The gate driver 300, data driver 400, timing controller 600, and gamma voltage generator 700 may be represented by the display driver 500.

As shown in FIG. 2, the transparent display device 1000A according to one or more embodiments may further include a light shield panel 1100 disposed on a back side of the display panel 100 and overlapping with the display panel 100, and a light shield panel driver 1200 driving the light shield panel 1100.

As shown in FIGS. 1 and 2, the display panel 100 may be a rigid display panel or a flexible display panel that can be deformed, such as a foldable, bendable, rollable, or stretchable display panel.

The display panel 100 is a transparent display panel that allows a background located behind the display panel 100 to be viewed through the display panel 100. The display panel 100 may include a display area AA in which a plurality of pixel areas PX are arranged in a matrix to display an image, and a bezel area located around the display area AA. The display panel 100, according to one or more embodiments, may be a panel with a touch sensor screen embedded or attached while being superimposed on the display area AA.

Each of the plurality of pixel regions PX may include an emissive area EA where a plurality of subpixels displaying an on-screen image are disposed, and a transmissive area TA that transmits light. The emissive area EA may be represented by a non-transmissive region, and the transmissive area TA may be represented by a transparent region.

As shown in FIGS. 3A to 4C, each of the pixel regions PX11, PX12, PX13, PX21, PX22, and PX23 according to various embodiments may include a non-transmissive area NTA with first to fourth subpixels SP1, SP2, SP3, SP4 arranged side-by-side in a first direction Y (vertical direction), and a transmissive area TA adjacent to the non-transmissive area NTA in a second direction X (horizontal direction). The non-transmissive area NTA may include first to fourth emissive regions EA1, EA2, EA3, and EA4 of the first to fourth subpixels SP1, SP2, SP3, and SP4 arranged side-by-side in the first direction Y (vertical direction), and a black matrix BM surrounding the emissive regions EA1, EA2, EA3, and EA4.

The first type pixel area PX11 according to one or more embodiments and the second type pixel area PX21 according to one or more embodiments may have a structure in which the non-transmissive area NTA is disposed on the left side and the transmissive area TA is disposed on the right side.

The first type pixel area PX12 according to one or more embodiments and the second type pixel area PX22 according to one or more embodiments may have a structure in which the non-transmissive area NTA is disposed on the right side and the transmissive area TA is disposed on the left side.

The first type pixel area PX13 according to one or more embodiments and the second type pixel area PX23 according to one or more embodiments may have a structure in which the non-transmissive area NTA is disposed in the center and the transmissive area TA is disposed on both the left and right sides of the non-transmissive area NTA.

The first to fourth emission regions EA1, EA2, EA3, and EA4 of the first to fourth subpixels SP1, SP2, SP3, and SP4 may be disposed on the first to fourth row lines RL1, RL2, RL3, and RLA arranged side by side in the first direction Y, respectively.

As shown in FIGS. 3A to 3C, the first type of pixel regions PX11, PX12, and PX13 may include blue (hereinafter B), white (hereinafter W), green (hereinafter G), and red (hereinafter R) subpixels SP1, SP2, SP3, and SP4 sequentially arranged in the first direction Y in the non-transmissive area NTA.

As shown in FIGS. 4A to 4C, the second type of pixel regions PX21, PX22, and PX23 may include R, G, W, B subpixels SP1, SP2, SP3, and SP4 sequentially arranged in the first direction Y in the non-transmissive area NTA.

As shown in FIGS. 3A to 4C, in each of the pixel regions PX11, PX12, PX13, PX21, PX22, and PX23 according to various embodiments, the G, W subpixels may be centered in the non-transmissive area NTA in the first direction Y. Accordingly, edge artifacts such as white lines and black lines that may occur at the edges of the image pattern due to separation or differences in the separation distance of the G and W subpixels between pixels can be avoided or reduced.

As shown in FIGS. 3A to 4C, in each of the pixel regions PX11, PX12, PX13, PX21, PX22, and PX23 according to various embodiments, the R subpixel may be disposed adjacent to the G subpixel in the first direction Y. Accordingly, color fringe artifacts that may occur at the edges of the image pattern due to the separation distance of the R and G subpixels between the pixels may be prevented or reduced.

As shown in FIGS. 3A to 4C, one of the second and third subpixels SP2 and SP3 centered in the first direction Y in each of the pixel regions PX11, PX12, PX13, PX21, PX22 and PX23 according to various embodiments may be a G subpixel and the other may be a W subpixel. As shown in FIGS. 4A to 4C, if the second subpixel SP2 is a G subpixel, the first subpixel SP1 may be an R subpixel, the third subpixel SP3 may be a W subpixel, and the fourth subpixel SP4 may be a B subpixel. As shown in FIGS. 3A to 3C, if the third subpixel SP3 is a G subpixel, the fourth subpixel SP4 is an R subpixel, the first subpixel SP1 is a B subpixel, and the second subpixel SP2 is a W subpixel.

Each of the plurality of subpixels SP1 to SP2 may include a light emitting element and a pixel circuit independently driving the light emitting element. The light-emitting element may be an organic light-emitting diode, a quantum dot light-emitting diode, or an inorganic light-emitting diode. The pixel circuit may comprise TFTs of various configurations, including a driving TFT driving the light emitting element and a switching TFT delivering data signals to the driving TFT, and a storage capacitor storing the drive voltage of the driving TFT. The pixel circuitry is electrically connected with signal lines including gate lines, data lines, power lines, and the like disposed in the display panel 100.

The power management circuits 800, 800A can utilize the externally supplied input voltage to generate and output various drive voltages for operation of all configurations of the transparent display device, namely the display panel 100 and the display driver 500. The power management circuit 800A can further supply the drive voltages to drive the light shield panel 1100 and the light shield panel driver 1200.

The gate driver 300 may be controlled according to a plurality of gate control signals supplied from the timing controller 600 and may individually drive gate lines of the display panel 100. The gate driver 300 may supply a scan signal of a gate-on voltage to the corresponding gate line during a drive period of each gate line, and may supply a gate-off voltage to the corresponding gate line during a non-drive period of each gate line. The gate driver 300 may be embedded in a bezel area of the display panel 100 in the form of a Gate In Panel (GIP) formed with the TFTs in the display area AA.

The gate driver 300 embedded in the display panel 100 according to one or more embodiments may receive a plurality of gate control signals from the timing controller 600 via a level shifter. The level shifter may receive the control signals from the timing controller 600 and level-shift or logic process them to generate a plurality of gate control signals and supply them to the gate driver 300.

The gamma voltage generator 700 generates a plurality of reference gamma voltages with different gamma voltage levels and supplies them to the data driver 400. The gamma voltage generator 700 may generate a plurality of reference gamma voltages corresponding to a gamma characteristic of the display device under control of the timing controller 600 and supply them to the data driver 400. The gamma voltage generator 700 may adjust the reference gamma voltage levels according to the gamma data supplied from the timing controller 600 and output them to the data driver 400. The gamma voltage generator 700 may adjust a high-potential power supply voltage that is a maximum gamma voltage according to the peak luminance control from the timing controller 600, and may adjust a plurality of reference gamma voltages according to the adjusted high-potential power supply voltage and output them to the data driver 400.

The data driver 400 may be controlled according to a data control signal supplied from the timing controller 600, and may convert the digital data supplied from the timing controller 600 to an analog data signal using a digital-to-analog conversion circuit. The data driver 400 may subdivide the plurality of reference gamma voltages supplied from the gamma voltage generator 700 into gradient voltages, and convert the digital data into analog data signals using the subdivided gradient voltages. The data driver 400 can supply the converted data signals to the data lines of the display panel 100.

Additionally, the data driver 400 may supply a reference voltage to the reference line of the display panel 100 under control of the timing controller 600. The data driver 400 can supply the reference voltage separately for display and sensing purposes under the control of the timing controller 600.

The data driver 400 may sense a signal reflecting the driving characteristics of each of the subpixels SP1 to SP4 via the reference line using the sensing part in a voltage sensing method or a current sensing method under the control of the timing controller 600.

The timing controller 600 may receive source image data and timing control signals from a host system. The host system may be one of a computer, a television system, a set-top box, a system on a mobile device such as a tablet or cell phone, or a system in an automobile. The timing control signals may include a dot clock, a data enable signal, a vertical synchronization signal, a horizontal synchronization signal, and the like.

The timing controller 600 can control the gate driver 300 and the data driver 400 using timing control signals supplied from the host system and internally stored timing setup information. The timing controller 600 can generate a plurality of gate control signals that control the drive timing of the gate driver 300 and supply them to the gate driver 300. The timing controller 600 can generate a plurality of data control signals that control the drive timing of the data driver 400 and supply them to the data driver 400.

The timing controller 600 may perform various image processing on the input image data supplied from the host system, including image quality correction, degradation correction, luminance correction to reduce power consumption, and the like, and may supply the image processed data to the data driver 400. The timing controller 600 may be represented as an image processing unit.

In one or more embodiments, the timing controller 600 may utilize a Peak Luminance Control (PLC) method to control peak luminance based on the image data. The timing controller 600 can determine an Average Picture Level (APL) of the image data, and the higher the APL, the lower the peak luminance can be set to reduce power consumption.

In one or more embodiments, the timing controller 600 may cause the display device 1000 to operate in a sensing mode. In sensing mode, the timing controller 600 may receive sensing data that senses electrical characteristics of the display panel 100 via sensing circuitry embedded in either of the data driver 400 and the power management circuitry 800, 800A.

In one or more embodiments, the timing controller 600 may accumulate the image data and determine a sensing region by predicting a degraded region in the display panel 100 based on the accumulated data. In sensing mode, the timing controller 600 may be supplied with sensing data that senses electrical characteristics of the sensing region of the display panel 100 using the data driver 400 or the power management circuitry 800, 800A.

Based on the sensing data, the timing controller 600 may calculate the amount of change in electrical characteristics (threshold voltage shift values) of the driving transistors and/or light emitting elements of each subpixel SP1, SP2, SP3, SP4, and may calculate and store in memory a compensation value to compensate for the change. The timing controller 600 may compensate the image data by applying the compensation value stored in the memory to compensate for luminance deviations due to deviations in the characteristics of each subpixel SP1, SP2, SP3, SP4, or to compensate for afterimages due to degradation.

The sensing modes of the display devices 1000, 1000A according to one or more embodiments may be performed in accordance with instructions from the host system, may be performed by a user request via the host system, or may be performed in accordance with a drive sequence determined by the timing controller 600.

As shown in FIG. 2, the transparent display device 1000A according to one or more embodiments may operate in an on-screen critical mode and a see-through critical mode by controlling the light transmittance of the light shield panel 1100. The on-screen critical mode may include a normal mode for displaying a TV image or the like. The see-through critical mode may include a transparent mode.

The timing controller 600 may determine the on-screen critical mode and the see-through critical mode based on the type of input video. When in the on-screen critical mode, the timing controller 600 is operated in a normal mode, and under the control of the timing controller 600, the light shield panel driver 1200 may operate the light shield panel 1100 in a shading mode that displays black. Accordingly, the display panel 100 may display an on-screen image utilizing the pixel areas PX on a black background of the light shield panel 1100 visible through the transmissive area TA to improve the visibility of the on-screen image.

When in the see-through critical mode, the light shield panel driver 1200, under the control of the timing controller 600, may drive the light shield panel 1100 in the see-through mode. Accordingly, the viewer can see the on-screen image displayed by the pixel areas PA, with the back background visible through the transmissive area TA of the display panel 100 and the light shield panel 1100.

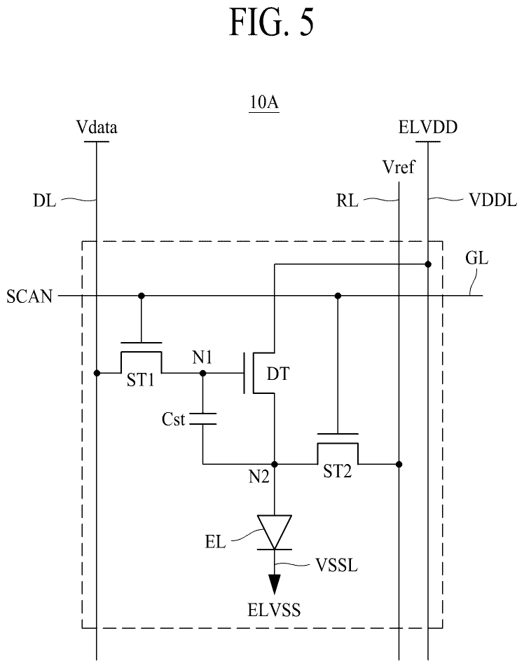

FIG. 5 is an equivalent circuit illustrating an example of the configuration of each subpixel according to one or more embodiments of the present disclosure.

As shown in FIG. 5, each subpixel 10A includes a light-emitting element EL connected between a first power line VDDL supplying a high-potential drive voltage ELVDD (first power supply voltage) and a second power line VSSL supplying a low-potential drive voltage ELVSS (second power supply voltage), a pixel circuit including first and second switching TFTs ST1, ST2 and a driving TFT DT and a storage capacitor Cst to independently drive the light emitting element EL.

The light emitting element EL may have an anode connected with a source node N2 of the driving TFT DT, a cathode connected with a second power line VSSL, and an organic light emitting layer between the anode and the cathode. The anodes may be independent per subpixel, but the cathode may be a common electrode shared by all subpixels. The light-emitting element EL may generate light of a luminance proportional to the current value of the drive current by injecting electrons from the cathode into the organic light-emitting layer and holes from the anode into the organic light-emitting layer when a drive current is supplied from the driving TFT DT, and by emitting a fluorescent or phosphorescent material by recombination of electrons and holes in the organic light-emitting layer.

The first switching TFT ST1 is driven by a scan signal SCAN supplied to the gate line GL from the gate driver 300, and a data voltage Vdata supplied to the data line DL from the data driver 400 can be supplied to the gate node N1 of the driving TFT DT.

The second switching TFT ST2 may be driven by a scan signal SCAN supplied to the gate line GL from the gate driver 300, and a reference voltage Vref supplied to the reference line RL from the data driver 400 may be supplied to the source node N2 of the driving TFT DT. On the other hand, in the sensing mode, the second switching TFT ST2 may provide a current reflecting the characteristics of the driving TFT DT or the characteristics of the light emitting element EL to the reference line RL.

The first and second switching TFTs ST1, ST2 may be controlled by the same gate line, or may be controlled by different gate lines, as shown in FIG. 5.

The storage capacitor Cst connected between the gate node N1 and the source node N2 of the driving TFT DT charges the differential voltage of the data voltage Vdata and the reference voltage Vref supplied to the gate node N1 and the source node N2 through the first and second switching TFTs ST1, ST2, respectively, to the drive voltage (Vgs) of the driving TFT DT, and holds the charged drive voltage Vgs during the light emission period when the first and second switching TFTs ST1, ST2 are turned off.

The driving TFT DT can control the light emission intensity of the light emitting element EL by controlling the current Ids flowing to the light emitting element EL according to the driving voltage Vgs charged in the storage capacitor Cst.

In FIG. 5, the gate line GL may be driven by the gate driver 300, receive a data voltage Vdata and a reference voltage Vref from the data driver 400, and receive a high-potential drive voltage ELVDD and a low-potential drive voltage ELVSS from the power management circuits 800, 800A.

FIG. 6 is an equivalent circuit diagram illustrating an example of the configuration of each subpixel according to one or more embodiments of the present disclosure.

As shown in FIG. 6, each subpixel 10B may include a light emitting element EL, and a pixel circuit including a driving TFT DT that supplies current to the light emitting element EL, a plurality of TFTs T1 to T6, and a storage capacitor Cst. The TFTs in each pixel circuit may be TFTs utilizing any one of polysilicon semiconductor, amorphous silicon semiconductor, and oxide semiconductor.

For example, the driving TFT DT and the TFTs T1 to T6 may comprise a polysilicon TFT with a P-type channel utilizing fast-mobility polysilicon.

On the other hand, the driving TFT DT and the TFTs T1 to T3, T5 to T6 may be composed of a polysilicon TFT with a P-type channel, and the compensation TFT T4 connecting the driving TFT DT with a diode structure may be composed of an oxide TFT with an N-type channel using an oxide semiconductor having a smaller leakage current than polysilicon. The fourth switching TFT T4 may block the leakage current to prevent flicker during low-speed operation when the screen update rate is relatively slow.

The light emitting element EL may comprise an anode connected to the drain electrode of the driving TFT DT via the light emission control TFT T5, a cathode connected to the second power line 110 supplying the second power supply voltage ELVSS, and an organic light emitting layer between the anode and the cathode. The light emitting element EL may generate light of a luminance proportional to the current value of the drive current supplied from the driving TFT DT.

The compensation TFT T4 may be controlled by the first gate line 104 and can connect a second node N2 connected with the gate electrode of the driving TFT DT and a third node N3 connected with the drain electrode of the driving TFT DT. The compensation TFT T4 can be turned on by a gate-on voltage of the first gate signal SC1 [n] supplied through the first gate line 104, connecting the gate electrode and the drain electrode of the driving TFT DT, thereby connecting the driving TFT DT into a diode structure. The first gate line 104 may be disposed on two row lines, namely the n−1st and nth (where n is an integer greater than or equal to 2) row lines, which may reduce the size of the gate driver 300 embedded in the bezel area of the display panel 100 and the size of the bezel.

The switching TFT T1 is controlled by the second gate line 105 and can connect the data line 102 with the first node N1 which is connected to the source electrode of the driving TFT DT. The switching TFT T1 can be turned on by a gate-on voltage of the second gate signal SC2 [n] supplied via the second gate line 105, and can supply a data voltage Vdata supplied via the data line 102 to the source electrode of the driving TFT DT.

The operation control TFT T2 is controlled by the light emission control line 111 and can connect the first power line 103 with the first node N1 connected to the source electrode of the driving TFT DT. The operation control TFT T2 can be turned on by the gate-on voltage of the light emission control signal EM [n] supplied via the light emission control line 111, and can supply the first power supply voltage ELVDD supplied via the first power line 103 to the source electrode of the driving TFT DT.

The light emission control TFT T5 is controlled by the light emission control line 111 and can connect a third node N3 connected to the drain electrode of the driving TFT DT with a fourth node N4 connected to the anode electrode of the light emitting element EL. The light emission control TFT T5 can be turned on by a gate-on voltage of the light emission control signal EM [n] supplied via the light emission control line 111, and can connect the drain electrode of the driving TFT DT with the anode electrode of the light emitting element EL.

The first initialization TFT T3 is controlled by the third gate line 106 and can connect the third node N3 connected to the drain electrode of the driving TFT DT with the first initialization line 108. The first initialization TFT T3 can be turned on by a gate-on voltage of the third gate signal SC3 [n] supplied via the third gate line 106, and can supply the third node N3 connected to the drain electrode of the driving TFT DT with a first initialization voltage Vini supplied via the first initialization line 108.

The second initialization TFT T6 is controlled by the fourth gate line 107 and can connect to the second initialization line 109 with the fourth node N4 connected to an anode of the light emitting element EL. The second initialization TFT T6 may be turned on by a gate-on voltage of the fourth gate signal SC3 [n+1] supplied through the fourth gate line 107, and may supply the fourth node N4 connected with the anode electrode of the light emitting element LED with a second initialization voltage (VAR, anode reset voltage) supplied through the second initialization line 109. The fourth gate line 107 may share a third gate line that supplies a third gate signal (SC3 [n+1]) on the n+1st (n is a positive integer) low line.

The storage capacitor Cst may be connected between the first power line 103 and the second node N2, which is connected to the gate electrode of the driving TFT DT. The storage capacitor Cst may be charged with a voltage differential between the first power supply voltage ELVDD supplied via the first power line 103 and the data voltage Vdata supplied to the second node N2. The data voltage Vdata may be supplied to the second node N2 from the data line 102 via the operation control TFT T2 and the driving TFT DT and the switching TFT T1. While the driving TFT DT is connected to the diode structure via the compensation TFT T4, the storage capacitor Cst may sample and store the threshold voltage Vth of the driving TFT DT, and may provide a data voltage (Vdata+Vth) compensated by the threshold voltage Vth to the gate electrode of the driving TFT DT. Accordingly, the storage capacitor Cst may be charged with a target voltage that is a differential voltage between the first power supply voltage ELVDD and the data voltage (Vdata) compensated with the threshold voltage Vth of the driving TFT DT, and the charged target voltage may be provided as a drive voltage Vgs between the gate-source electrodes of the driving TFT DT. Thus, the characteristic deviation of the driving TFT DT between subpixels may be compensated.

The driving TFT DT may control the light emission intensity of the light emitting element EL by controlling the current Ids flowing to the light emitting element EL according to the drive voltage charged in the storage capacitor Cst.

In FIG. 6, the gate lines 104, 105, 106, 107 may be driven by the gate driver 300, and the light emission control line 111 may be driven by a light emission control driver embedded in the gate driver 300 and disposed in the bezel area of the display panel 100. A data voltage Vdata may be supplied from the data driver 400. A first power supply voltage ELVDD, a second power supply voltage ELVSS, a first initialization voltage Vini, and a second initialization voltage VAR may be supplied from the power management circuits 800, 800A.

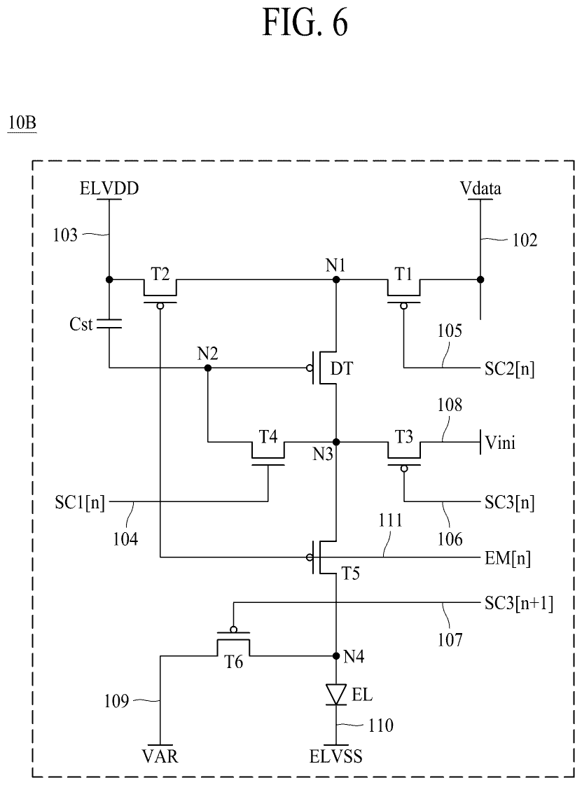

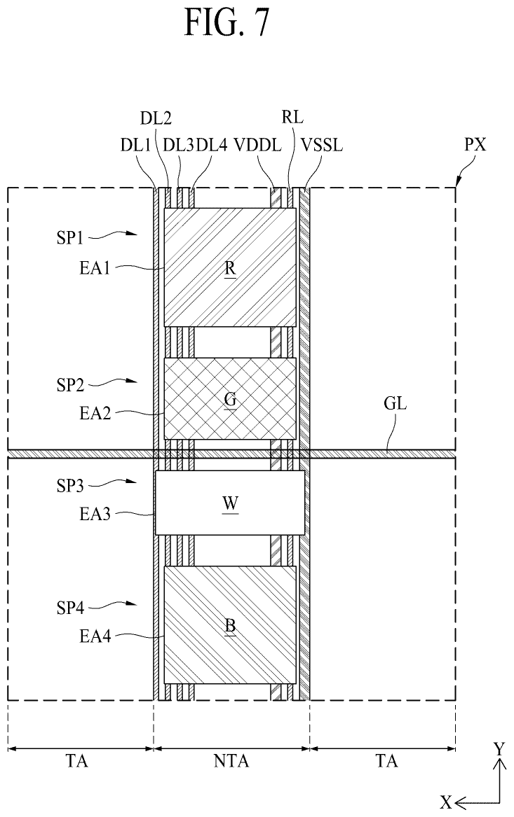

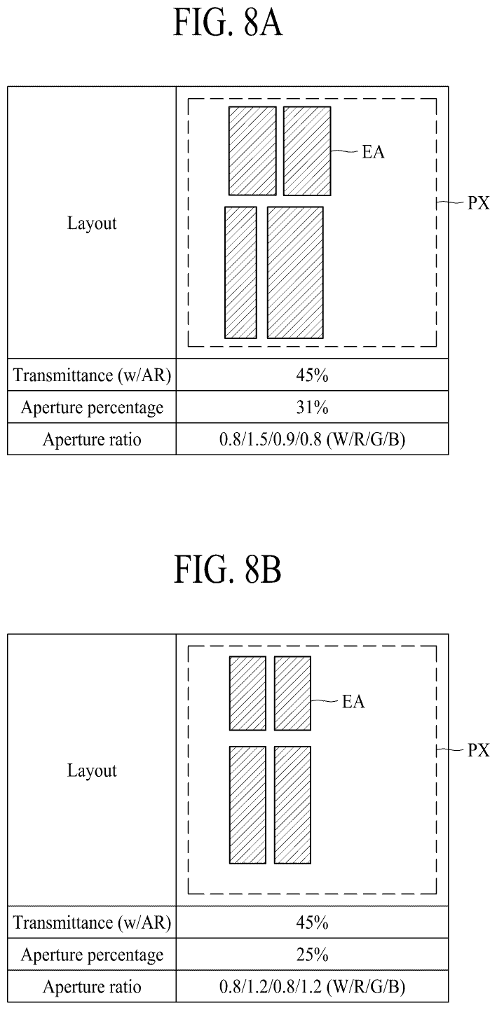

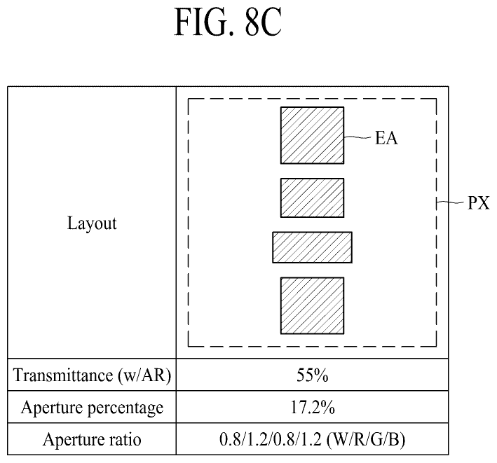

FIG. 7 is an example diagram illustrating an example of a respective pixel area according to an embodiment of the present disclosure, and FIGS. 8A to 8C are diagrams illustrating transmittance of a transparent display device according to an embodiment of the present disclosure compared to a transparent display device according to a comparative example.

As shown in FIG. 7, a pixel area PX according to one or more embodiments may include a non-transmissive area NTA disposed in the center of a second direction X, and a transmissive area TA disposed on either side of the non-transmissive area NTA in the second direction X. The non-transmissive area NTA may include light emitting regions EA1 to EA4 of R, G, W, and B subpixels SP1, SP2, SP3, SP4 arranged side-by-side and sequentially in the first direction Y. The pixel circuits of the R, G, W, B subpixels SP1, SP2, SP3, SP4 may be provided below the light emitting regions EA1 to EA4 while being overlapped with the light emitting regions EA1 to EA4.

The R, G, W, B subpixels SP1, SP2, SP3, SP4 may be individually connected with the first to fourth data lines DLI to DLA extending along the first direction Y from the left side of the non-transmissive area NTA and disposed side by side in the second direction X. The R, G, W, and B subpixels SP1, SP2, SP3, and SP4 may be connected in common with each of the first power line VDDL, reference line RL, and second power line VSSL extending along the first direction Y from the right side of the non-transmissive area NTA and disposed side by side in the second direction X. The R, G, W, B subpixels SP1, SP2, SP3, SP4 may be in common connection with a gate line GL extending in the second direction X.

As shown in FIGS. 8A to 8C, the transmittance (55%) of the pixel area (PX) according to an embodiment having a vertical array structure in which the light emission areas EAs of the four-color (R, G, W, B) subpixels are arranged side by side in a vertical direction, as shown in FIG. 8C is improved over the transmittance (45%) of the pixel area (PX) according to a comparative example in which the light-emitting areas EAs of the four-color (R, G, W, B) subpixels are arranged in a matrix form as shown in FIGS. 8A and 8B.

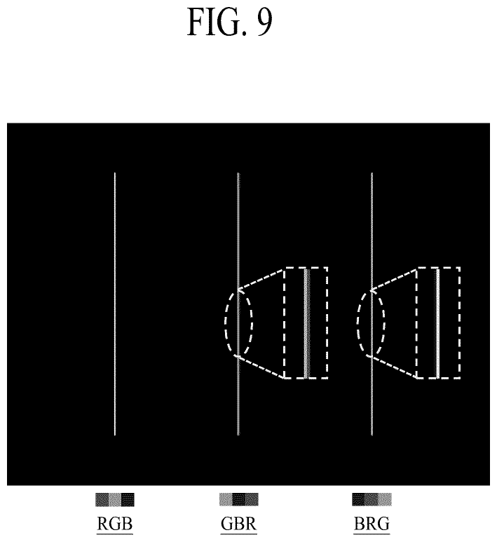

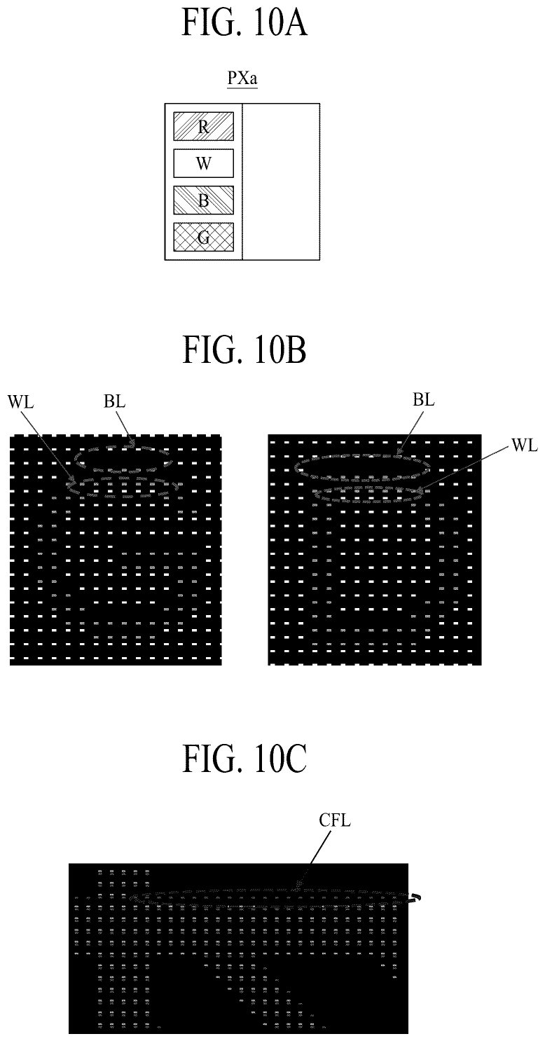

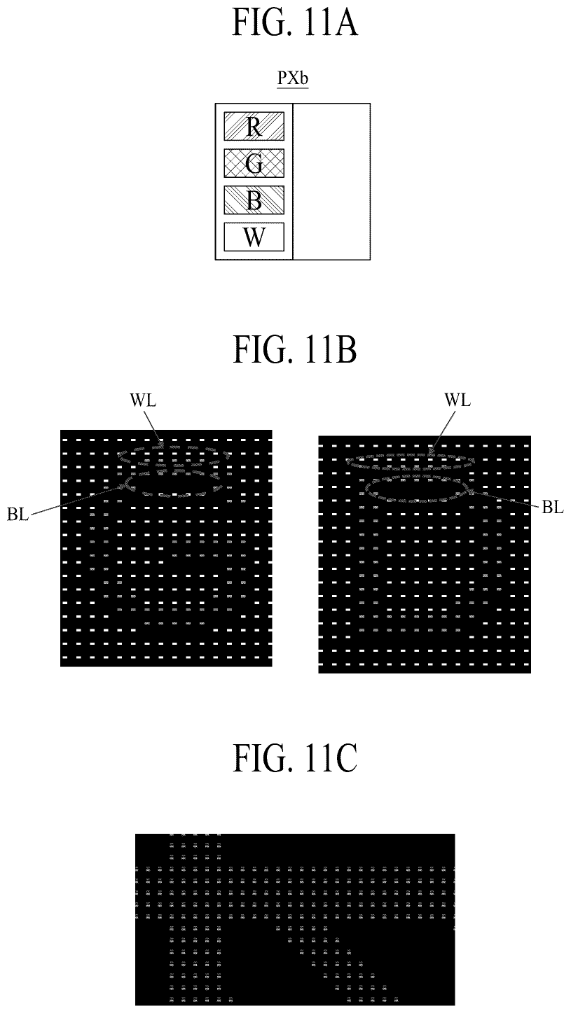

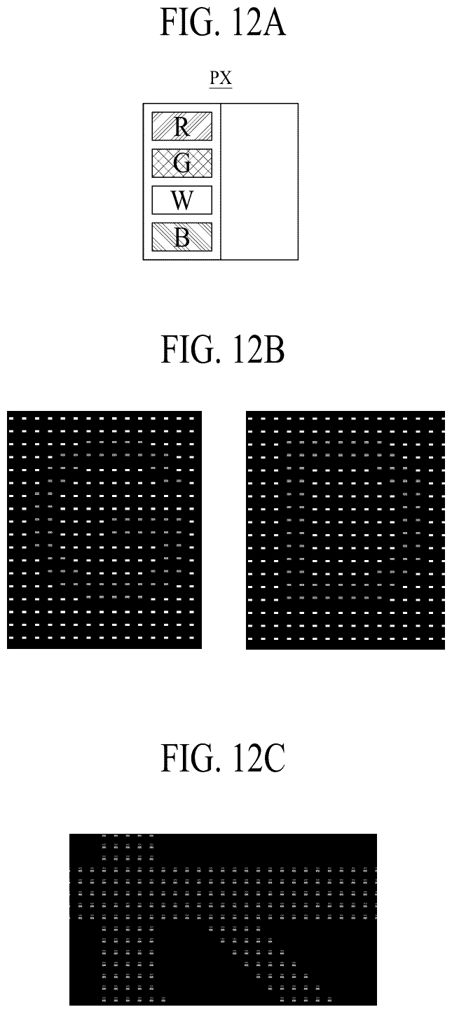

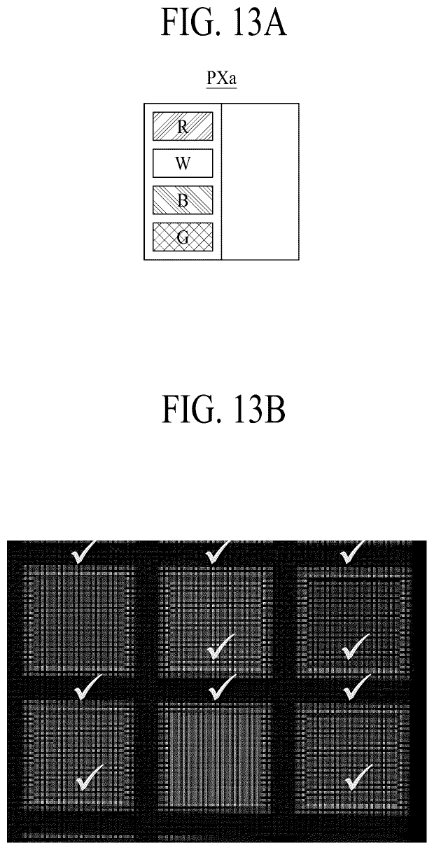

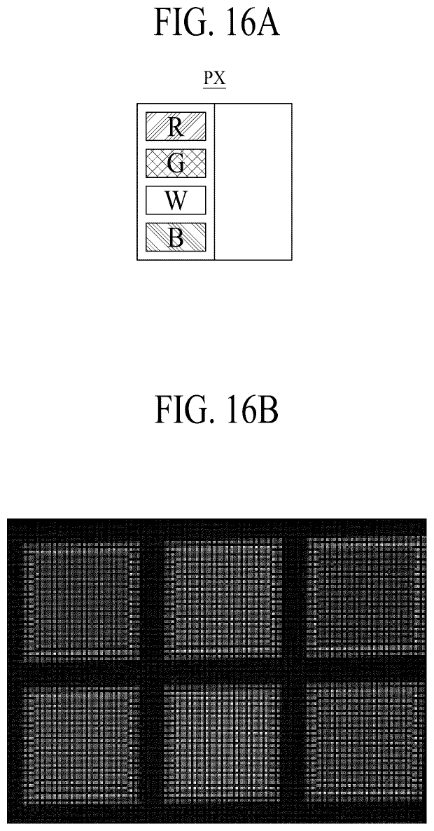

FIG. 9 is an illustration of a color fringe according to an arrangement order of three-color subpixels according to a comparative example, FIGS. 10A to 11C are diagrams illustrating an example of an edge artifact phenomena of a transparent display device according to a comparative example, and FIGS. 12A to 12C are diagrams illustrating examples of an edge artifact mitigation effect of a transparent display device according to an embodiment of the present disclosure, FIGS. 13A to 15B are drawings illustrating examples of edge artifacts of a transparent display device according to a comparative example, and FIGS. 16A and 16B are drawings illustrating examples of edge artifact mitigation effects of a transparent display device according to an embodiment of the present disclosure.

As shown in FIG. 9, it can be seen that in a stripe basic structure of three-color (R, G, B) subpixels, an RGB array structure in which the G subpixel is centered can display a white line without color fringe. On the other hand, when displaying white lines using the GBR array structure with G subpixels skewed to the left, red color fringe may occur at the right edge of the white line, and when displaying white lines using the BRG array structure with G subpixels skewed to the right, blue color fringe may occur at the left edge of the white line. When the R and G subpixels are spaced apart with another subpixel (B) in between, as in the GBR array structure, the color fringe is more perceptible.

As shown in FIGS. 10A to 10C, FIG. 13A, and FIG. 13B, it can be seen in the pixel area PXa that the G subpixel is not centered and the R and G subpixels are spaced apart from each other with the W and B subpixels therebetween, for the display device according to the comparative example utilizing the pixel area PXa according to the comparative example in which the R/W/B/G subpixels are sequentially arranged in the vertical direction as shown in FIGS. 10A and 13A. Accordingly, it can be seen that the display device according to the comparative example may have black lines (BL) and white lines (WL) at the edges of the letter patterns G, D shown in green on a white background, as shown in FIG. 10B, or red color fringe at the edges of the line patterns shown in yellow, as shown in FIG. 10C, or edge artifacts such as white lines, black lines, and color fringe at the edges of the box patterns of various colors, as shown in FIG. 13B.

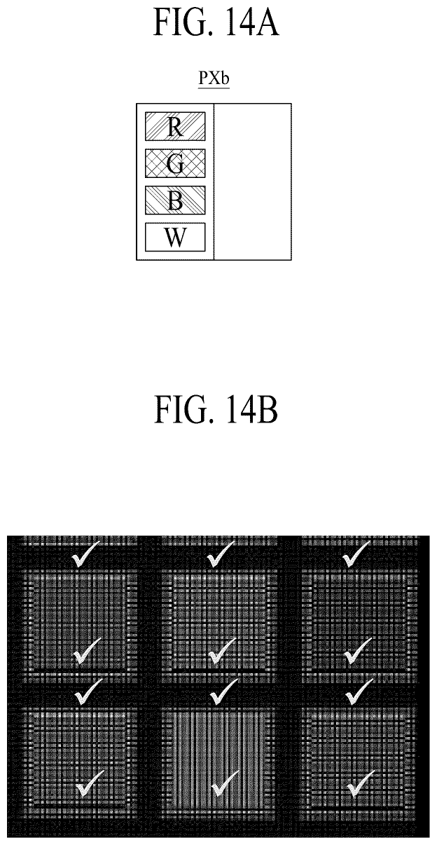

As shown in FIGS. 11A to 11C, FIG. 14A, and FIG. 14B, it can be seen that in the display device according to the comparative example utilizing the pixel area PXb according to the comparative example in which the R/G/B/W subpixels are sequentially arranged in the vertical direction as shown in FIGS. 11A and 14A, the W subpixel is not centered in the pixel area PXb. Accordingly, it can be seen that the display device according to the comparative example may have black lines (BL) and white lines (WL) at the edges of the letter patterns G, D shown in green on a white background, as shown in FIG. 11B, or artifacts such as white lines and black lines at the edges of various color patterns, as shown in FIG. 14B. However, it can be seen that the display device according to the comparative example does not generate color fringe artifacts in the yellow line pattern as shown in FIG. 10C due to the adjacent placement of the R and G subpixels in the pixel region PXb.

As shown in FIGS. 12A to 12C, FIG. 16A, and FIG. 16B, it can be seen that in the display device according to one or more embodiments utilizing a pixel area PX according to one or more embodiments in which the R/G/W/B subpixels are sequentially arranged in the vertical direction as shown in FIGS. 12A and 16A, the G and W subpixels are centered in the pixel area (PX), the R and G subpixels are adjacent. Accordingly, it can be seen that the display apparatus according to one or more embodiments does not generate black lines or white lines artifacts at the edges of the letter patterns G, D shown in green on a white background as shown in FIG. 12B, does not generate color fringe artifacts in the yellow line pattern as shown in FIG. 12C, and does not generate edge artifacts such as white lines, dark lines, and color fringe artifacts at the edges of various color patterns as shown in FIG. 16B.

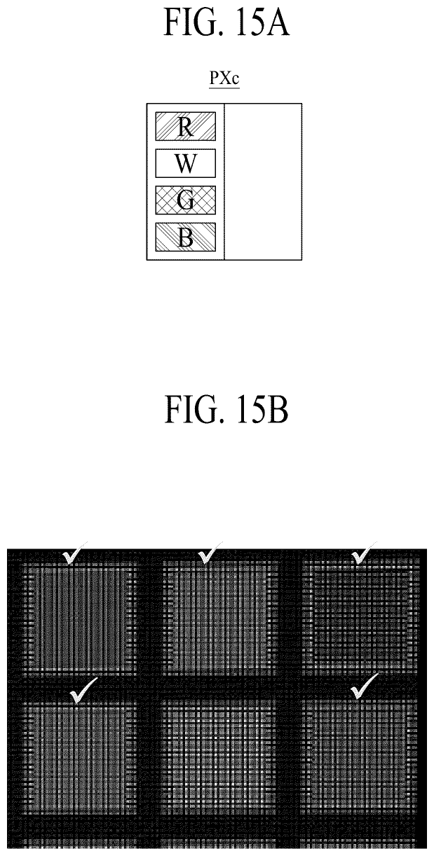

As shown in FIGS. 15A and 15B, it can be seen that in the display device according to the comparative example utilizing the pixel area PXc according to the comparative example in which the R/W/G/B subpixels are sequentially arranged in the vertical direction as shown in FIG. 15A, the R and G subpixels are spaced apart from each other with the W subpixels therebetween in the pixel area PXc. Accordingly, the display device according to the comparative example may be able to generate edge artifacts such as color fringe at various color pattern edges, as shown in FIG. 15B.

As described above, the transparent display device according to one or more embodiments can improve image quality by mitigating edge artifacts such as black lines, white lines, and color fringe by having the green and white subpixels among the four color subpixels in the non-transmissive region of each pixel region disposed in the center of the non-transmissive region, and the red and green subpixels disposed adjacent to each other.

The transparent display device according to one or more embodiments may include red/green/white/blue or blue/white/green/red subpixels to be arranged side by side in a vertical direction in a non-transmissive region of each pixel region to improve image quality by mitigating edge artifacts such as white lines, black lines, and color fringe, and may achieve a low power consumption effect by increasing the transmissive region to improve transmittance.

A transparent display device according to one or more embodiments may include a plurality of pixel regions including a non-transmissive region and a transmissive region, wherein the non-transmissive region of each pixel region includes a first subpixel, a second subpixel, a third subpixel, and a fourth subpixel arranged sequentially in this order in a first direction. One of the second and third subpixels may be a green subpixel, and the other may be a white subpixel. The first subpixel may be a red subpixel if the second subpixel is a green subpixel, and the fourth subpixel may be a red subpixel if the third subpixel is a green subpixel.

In a transparent display device according to one or more embodiments, the first to fourth subpixels may be a red subpixel, a green subpixel, a white subpixel, and a blue subpixel arranged sequentially in the first direction.

In a transparent display device according to an embodiment, the first to fourth subpixels may be a blue subpixel, a white subpixel, a green subpixel, and a red subpixel sequentially arranged in the first direction.

In each pixel region of the transparent display device according to one or more embodiments, the transmissive region may be disposed in a region to the left or right of the non-transmissive region, or may be disposed in a region to both the left and right of the non-transmissive region.

The transparent display device according to one or more embodiments may include a plurality of pixel regions including a non-transmissive region and a transmissive region, wherein the non-transmissive region of each pixel region may include a red subpixel, a green subpixel, a white subpixel, and a blue subpixel arranged sequentially in this order in a vertical direction.

The transparent display device according to one or more embodiments may include a plurality of pixel regions including a non-transmissive region and a transmissive region, wherein the non-transmissive region of each pixel region may include a blue subpixel, a white subpixel, a green subpixel, and a red subpixel sequentially arranged in a vertical direction.

The transparent display devices according to one or more embodiments of the present disclosure can be applied to a variety of electronic devices. For example, the transparent display devices according to one or more embodiments of the present disclosure can be applied to mobile device, video phone, smart watch, watch phone, wearable device, foldable device, rollable device, bendable device, flexible device, curved device, navigation, in-vehicle navigation, in-vehicle display devices, televisions, wall paper display devices, signage devices, and home appliances.

The above-described feature, structure, and effect of the present disclosure are included in at least one or more embodiments of the present disclosure, but are not limited to only one or more disclosed embodiments. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the protected scope of the present disclosure is represented by the following claims and their equivalents, and all changes or modifications derived from the meaning, range, and equivalent concept of the claims should be interpreted as being included in the scope of the present disclosure.

What is claimed is:

1. A transparent display device, comprising:
a display area having a plurality of pixel regions having a non-transmissive region and a transmissive region; and
a first subpixel, a second subpixel, a third subpixel, and a fourth subpixel arranged sequentially in a first direction in the non-transmissive region of the plurality of pixel regions,
wherein one of the second subpixel and the third subpixel is a green subpixel, and the other is a white subpixel, and
wherein if the second subpixel is a green subpixel, the first subpixel is a red subpixel, or if the third subpixel is a green subpixel, the fourth subpixel is a red subpixel.

2. The transparent display device according to claim 1,
wherein the first to fourth subpixels are a red subpixel, a green subpixel, a white subpixel, and a blue subpixel arranged sequentially in the first direction.

3. The transparent display device according to claim 1,
wherein the first to fourth subpixels are a blue subpixel, a white subpixel, a green subpixel, and a red subpixel arranged sequentially in the first direction.

4. The transparent display device according to claim 1,
wherein the transmissive region is provided at a left or right side of the non-transmissive region, or at both of the left and right sides of the non-transmissive region in the plurality of pixel regions.

5. The transparent display device according to claim 1,
wherein the first direction is a vertical direction, and the second subpixel and the third subpixel are centered in the non-transmissive region in the first direction.

6. A transparent display device, comprising:
a display area having a plurality of pixel regions having a non-transmissive region and a transmissive region; and
a red subpixel, a green subpixel, a white subpixel, and a blue subpixel arranged sequentially in a vertical direction in the non-transmissive region of the plurality of pixel regions.

7. The transparent display device according to claim 6,
wherein the transmissive region is provided at a left or right side of the non-transmissive region, or at both of the left and right sides of the non-transmissive region in the plurality of pixel regions.

8. A transparent display device comprising:
a display area having a plurality of pixel regions having a non-transmissive region and a transmissive region; and
a blue subpixel, a white subpixel, a green subpixel, and a red subpixel arranged sequentially in a vertical direction in the non-transmissive region of the plurality of pixel regions.

9. The transparent display device according to claim 8,
wherein the transmissive region is provided at a left or right side of the non-transmissive region, or at both of the left and right sides of the non-transmissive region in the plurality of pixel regions.

10. The transparent display device according to claim 8,
wherein the white subpixel and the green subpixel are centered in the non-transmissive region in the vertical direction.

11. The transparent display device according to claim 6,
wherein the white subpixel and the green subpixel are centered in the non-transmissive region in the vertical direction.
